(19) United States
(12) Patent Application Publication
(10) Pub. No.: US 2001/0024858 A1
(43) Pub. Date: Sep. 27, 2001

(54) Method for producing a vertical MOS transistor

(75) Inventors: Thomas Schulz, Munchen (DE); Thomas Aeugle, Munchen (DE); Wolfgang Roesner, Munchen (DE)

Correspondence Address: WERNER H. STEMER, P.O. Box 2480, Hollywood, FL, 33022, US

(73) Assignee: Infineon Technologies AG

(21) Appl. No.: 09/843,584

(22) Filed: Apr. 26, 2001

Related U.S. Application Data
(62) Division of application No. 09/530,169, filed on Aug. 22, 2000.
Application No. 09/530,169 is a continuation of application No. PCT/DE98/02946, filed on Oct. 5, 1998.

(30) Foreign Application Priority Data
Oct. 23, 1997 (DE) I97 46 900.0

(51) Int. Cl. H01L 21/336

(52) U.S. Cl. 438/268

(57) ABSTRACT

A first part (S/D1a) of a first source/drain region (S/D1) is disposed on at least one flank of a semiconductor structure (St) and on at least one peripheral region of a surface (OH), bordering the flank, of the semiconductor structure (St). A dimension of the first part (S/D1a) of the first source/drain region (S/D1) perpendicular to the flank is less than an analogous dimension of the semiconductor structure (St) and than the minimum feature size that can be made by the technology used. For the production, a mask that is used to create the semiconductor structure (St) can be reduced in size for the implantation of the first part (S/D1a) of the first source/drain region (S/D1). To make it easier to create a contact (K1) of the first source/drain region (S/D1), a second part (S/D1b) of the first source/drain region (S/D1) can be disposed in an inner region of the surface (OH) of the semiconductor structure (St). A dimension of the second part (S/D1b) of the first source/drain region (S/D1) perpendicular to the surface (OH) of the semiconductor structure (St) is smaller than an analogous dimension of the first part (S/D1a) of the first source/drain region (S/D1).

### CROSS-REFERENCE TO RELATED APPLICATION

This is a division of U.S. application No. 09/530,169, filed Aug. 22, 2000, which was a continuation of International Application No. PCT/DE98/02946, which designated the United States.

### BACKGROUND OF THE INVENTION

1. Field of the Invention

With a view to ever-faster components with a higher scale of integration, the feature sizes of integrated circuits decrease from one generation to the next. This is also true for CMOS technology. It is generally expected that by the year 2010, MOS transistors with a gate length of less 100 nm will be used (see for example “Roadmap of Semiconductor Technology”, Solid State Technology 3, 1995).

On the one hand, the attempt is made to develop planar MOS transistors with gate lengths of this kind by scaling of the present conventional CMOS technology (see for example A. Hori, H. Nakaoka, H. Umimoto, K. Yamashita, M. Takase, N. Shimizu, B. Mizuno, S. Odanaka, “A 0.05 μm-CMOS with Ultra Shallow Source/Drain Junctions Fabricated by 5 keV Ion Implantation and Rapid Thermal Annealing”, IEDM 1994, 485 and H. Hu, L. T. Su, Y. Yang, D. A. Antoniadis, H. I. Smith, “Channel and Source/Drain Engineering in High-Performance sub-0.1 μm NMOSFETs using X-Ray lithography”, Sympl. VLSI Technology, 17, 1994).

In parallel with this, vertical transistors are being studied. Since the channel length extends vertically with respect to one surface of a substrate, the surface area of a vertical transistor can be less than that of conventional planar transistors. A further reduction in the surface area is obtained by decreasing the channel width required for a certain current intensity, which is done by shortening the channel length. In L. Risch, W. H. Krautschneider, F. Hofmann, H. Schäfer, “Vertical MOS Transistor with 70 nm channel length”, ESSDERC 1995, pp. 101-104, vertical MOS transistors with short channel lengths are described. For their production, layer sequences are formed corresponding to the source, channel and drain, and these are surrounded annularly by the gate dielectric and gate electrode. The channel length of the vertical MOS transistors is short in comparison with that of conventional planar transistors. By comparison with planar MOS transistors, the vertical MOS transistors have been unsatisfactory until now in terms of their high-frequency and logic properties. This is ascribed on the one hand to parasitic capacitances of the overlapping gate electrode and on the other to the development of a parasitic bipolar transistor in the vertical layer sequence.

H. Takato et al, IEDM 88, pp. 222-225, describe a vertical MOS transistor whose gate electrode annularly surrounds a block-shaped layer structure, in which a first source/drain region and a channel layer are disposed. Because of the annular disposition of the gate electrode, the space charge zone is increased in size, which brings about a reduction in the parasitic capacitance. The channel length of the MOS transistor is long and is equivalent to that of conventional planar transistors. The layer structure is created by a lithographic process and preferably has a lateral width of about 1 μm, so that the space charge zone fills the entire channel layer. The high-frequency and logic properties of the vertical MOS transistor are thus comparable to those of planar MOS transistors.

In the earlier but as yet unpublished German Patent Application 197 30 971.2, a method for producing a vertical MOS transistor is described in which a layer structure is created by an etching step, in which a spacer is used as a mask; on this layer structure, the MOS transistor is created on at least two opposed flanks. A first source/drain region forms one layer in the layer structure. Because of the spacerlike mask, a dimension of the first source/drain region perpendicular to the flanks is less than the minimal feature size F that can be made by the technology used. As in the MOS transistor of Takato, a channel forms in the entire channel region, and accordingly there are good high-frequency and logic properties.

In J. Schmitz, Y. Ponomarev, A. Montree and P. Woerlee, ESSDERC 97, pp. 224-227, a planar MOS transistor with source/drain regions doped with a first conductivity type is described, in which a region doped with a second conductivity type, opposite the first conductivity type, has been created in a channel region. Because of the doped region, the short-channel effects, such as punch-through, are lessened.

### SUMMARY OF THE INVENTION

The object of the invention is to disclose a method for producing a vertical MOS transistor in which the high-frequency and logic properties are comparable to those of planar MOS transistors and in which a channel length of the vertical MOS transistor can be especially short.

This object is attained by a vertical MOS transistor as defined by claim 1 and by a method for its production as defined by claim 5. Further features of the invention are disclosed by the remaining claims.

The vertical MOS transistor of the invention is disposed on at least one first flank of a semiconductor structure. In the semiconductor structure, bordering on a part of the first flank, there is a first source/drain region, doped with a first conductivity type. A second source/drain region is disposed lower than the first source/drain region with respect to a y axis that extends perpendicular to the surface of the semiconductor structure. The first source/drain region essentially borders on at least a peripheral region of the surface of the semiconductor structure. A first dimension of a first part of a first source/drain region perpendicular to the first flank is less than the minimum feature size F that can be made by the technology used, and as a result leakage currents generated by a parasitic bipolar transistor are reduced and the high-frequency and logic properties are improved. The first dimension of the first source/drain region is comparable to that of the first source/drain region from the earlier German patent application 197 30 971.2, but the semiconductor structure is larger and hence more stable than the layer structure of the earlier application 197 30 971.2. A gate dielectric and a gate electrode are disposed on the first flank.

It is advantageous if the MOS transistor is disposed on a plurality of first flanks of the semiconductor structure. First, this increases the channel width of the MOS transistor and thus the current intensity. Second, a channel occupies more space inside the channel region, which suppresses the parasitic bipolar transistor.

The first part of the first source/drain region can be created for instance by implantation with the aid of a mask that does not cover the peripheral region of the surface of the semiconductor structure. To that end, a first mask is applied for instance to a surface of a substrate that contains semiconductor material, such as silicon and/or germanium. By etching of semiconductor material, the semiconductor structure is created with the aid of the first mask. The first mask is reduced in size by isotropic etching, thus laying the peripheral region bare. By implantation with the aid of the reduced-size first mask, the first part of the first source/drain region is created. Alternatively, the first mask is applied to the surface of the substrate and enlarged by an auxiliary spacer, by deposition of material and back-etching. By etching of semiconductor material selectively to the first mask and to the auxiliary spacer, the semiconductor structure is created. The peripheral region of the surface of the semiconductor structure is laid bare by selective removal of the auxiliary spacer as far as the first mask. The first part of the first source/drain region is created by implantation with the aid of the first mask.

Instead of implantation, the first part of the first source/drain region can be created by depositing a doped material, for instance, from which dopant is subsequently diffused out.

It is within the scope of the invention that the first part of the first source/drain region forms the first source/drain region.

It is advantageous, bordering on a first part of the first source/drain region, in a substantially inner region of the surface of the semiconductor structure, to dispose a second part of the first source/drain region, whose second dimension is smaller relative to the y axis than a second dimension of the first part of the first source/drain region relative to the y axis. A larger surface area of the first source/drain region, widened by the second part of the first source/drain region, makes easier contacting of the first source/drain region possible. The leakage currents generated by parasitic bipolar transistor are kept slight because of the small second dimension of the second part of the first source/drain region relative to the y axis. For creating the second part of the first source/drain region, a first via-hole can for instance be created, by removing at least a first part of the first mask and then performing an implantation. Alternatively, the surface of the substrate is implanted before the semiconductor structure is created, for instance. A contact of the first source/drain region is preferably disposed in the first via-hole.

To reduce the short-channel effects, such as punch-through, it is advantageous to dispose a region doped with a second conductivity type, opposite the first conductivity type, underneath the inner region of the surface of the semiconductor structure, in the vicinity of the channel region.

It is within the scope of the invention to create the gate dielectric by thermal oxidation. The gate electrode can be created by deposition and etching of material. The material can be a conductive material, such as metal, doped amorphous silicon or doped polysilicon, or can for instance be polysilicon that is doped in a later process step. The gate electrode is created in the form of a spacer, for instance. Alternatively, as an example, the gate electrode can at least partly fill up part of an indentation that borders on the first flank. To simplify making a contact of the gate electrode, a region that includes a second flank of the semiconductor structure can be covered with a third mask during the etching of the material. On the second flank of the semiconductor structure, this creates a terminal for the gate electrode, and the surface area of this terminal perpendicular to the y axis can be selected to be so large that the contact of the gate electrode can be applied to the terminal without any problems of adjustment tolerance.

It is within the scope of the invention to dispose the second source/drain region underneath the first source/drain region. In this case, the semiconductor structure is formed by epitaxy.

It is advantageous if the second source/drain region is disposed laterally to the semiconductor structure. On the one hand, this reduces the leakage currents generated by a parasitic bipolar transistor. In addition, expensive epitaxy can be dispensed with. Furthermore, the lateral disposition enables the channel region to be connected to a potential via the substrate and not disconnected by the second source/drain region. To that end, the second source/drain region can be created by implantation after the semiconductor structure has been made. The second source/drain region is thus created in self-adjusted fashion, in other words without using masks that have to be adjusted, relative to the first source/drain region and to the gate electrode. The implantation of the second source/drain region can be done simultaneously with the implantation of the first part of the first source/drain region.

This step can also be taken after the gate electrode has been created. Then the gate electrode acts as a mask. To assure that in the triggering of the gate electrode a vertical channel of the MOS transistor can develop, it is advantageous to lengthen the second source/drain region as far as the first flank by diffusion underneath the gate electrode. If the diffusion does not suffice for this lengthening, then implantation can be done in addition before the gate electrode is created.

An especially favorable dopant distribution is attained if the first source/drain region is created by oblique implantation, after the creation of the gate electrode.

It is advantageous to lengthen the second source/drain region to the far side of the semiconductor structure. This allows the creation of a contact of the second source/drain region outside the semiconductor structure and above the second source/drain region, which is easily feasible.

To avoid lattice imperfections in the creation of the semiconductor structure, it is possible to use anisotropic etching, which does not create any lattice imperfections. If a conventional anisotropic etching is performed, it is advantageous to create a sacrificial layer by thermal oxidation and then to remove it by isotropic etching. This cleans the surfaces of lattice imperfections that occur in the creation of the semiconductor structure. The sacrificial layer can also act as a scattering oxide in the implantation of the second source/drain region.

It is advantageous, after the creation of the gate electrode, to deposit a thin film of silicon nitride. If the first part of the first source/drain region is created after the creation of the gate electrode, then the thin film of silicon nitride acts as a scattering layer. If a contact of the first source/drain region is applied above the second part of the first source/drain region, then the thin film of silicon nitride can serve as a lateral etching stop in the creation of the first via-hole.

It is within the scope of the invention to deposit a second layer, in which the first via-hole, a second via-hole for the contact of the second source/drain region, and a third via-hole for the contact of the gate electrode are created. The second layer can be deposited for instance with a thickness that is greater than that of the semiconductor structure, and can then be planarized afterward. Especially if no doped region is created, the first via-hole, second via-hole and third via-hole can be created simultaneously.

Other features which are considered as characteristic for the invention are set forth in the appended claims.

Although the invention is illustrated and described herein as embodied in a method for producing a vertical MOS transistor, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings

### BRIEF DESCRIPTION OF THE DRAWINGS

FIG. 1 shows a cross section through a first substrate, after the creation of a first mask, a second part of a first source/drain region, a semiconductor structure, and a second source/drain region.

FIG. 2 shows the cross section of FIG. 1, after the creation of a gate dielectric, a gate electrode, a thin film of silicon nitride, and a first part of the first source/drain region.

FIG. 3 shows the cross section of FIG. 2 after a second layer, a first via-hole, a doped region, a second via-hole, a contact for the first source/drain region, and a contact for the second source/drain region have all been created.

FIG. 4 shows a cross section through a second substrate after a first mask, an auxiliary spacer, and a semiconductor structure have been created.

FIG. 5 shows the cross section of FIG. 4, once a gate dielectric, a gate electrode, and, after the removal of the auxiliary spacer, a first part of a first source/drain region and a thin film have been created.

FIG. 6 shows the cross section of FIG. 5, once a second layer, a first via-hole, a second part of the first source/drain region, a doped region, a second via-hole, a contact of the first source/drain region, and a contact of the second source/drain region have all been created.

The drawings are not to scale.

### DESCRIPTION OF THE PREFERRED EMBODIMENTS

In the first exemplary embodiment, a substrate 1 of silicon is p-doped, in a layer S adjoining a surface O of the substrate 1. The dopant concentration of the layer S is approximately 10¹⁵ cm⁻³. By implantation, a thin layer or film SF, doped with a first conductivity type, is created at the surface O of the substrate 1. Since the implantation is done with an energy of about 20 keV, the doped thin film SF is about 50 nm deep. The dopant concentration of the doped thin film SF is about 10²¹ cm⁻³.

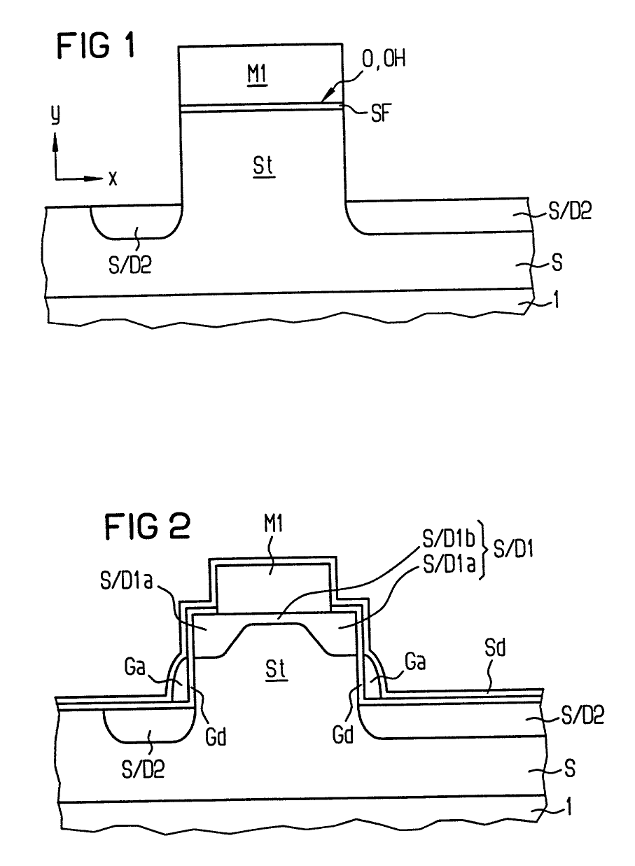

Next, in a TEOS process, a first layer or film of SiO₂ is created, which is about 150 nm thick. By a photolithographic process, a first mask M1 is created from the first layer; along an x axis x that extends parallel to the surface O of the substrate 1, this mask is about 600 nm long, and along a z axis, which is parallel to the surface O of the substrate 1 and perpendicular to the x axis x, it is about 2000 nm long (see FIG. 1).

For creating a semiconductor structure St, silicon is etched down to a depth of about 200 nm, with the aid of the first mask M1. As the etchant, HBr/NF₃/He,O₂ is for instance suitable (see FIG. 1).

Next, by thermal oxidation, a sacrificial layer (not shown) that is about 5 nm thick is created. By implantation with the aid of a second mask (not shown) that does not cover a region around first flanks of the semiconductor structure St, a second source/drain region S/D2, doped with the first conductivity type, is created. The sacrificial layer acts as a scattering oxide. The dopant concentration of the second source/drain region S/D2 is about 10²¹ cm⁻³. Next, by wet etching, for instance using HF, the sacrificial layer is removed, making the first mask M1 about 40 nm smaller in all dimensions. As a result of this step, surfaces created in the creation of the semiconductor structure St are cleaned of lattice imperfections.

Next, by thermal oxidation, a gate dielectric Gd about 4 nm thick is created.

To create a gate electrode Ga, in-situ-doped polysilicon is deposited to a thickness of about 150 nm. With the aid of a third mask (not shown), which covers a second flank of the semiconductor structure St and is extended to the far side of the semiconductor structure St, polysilicon is etched. As the etchant, HBr/NF₃/He,O₂ is for instance suitable. On the flanks of the semiconductor structure St, this creates a gate electrode Ga in the form of a spacer, and on the second flank it creates a terminal of the gate electrode Ga.

Next, a thin film Sd of silicon nitride is created by deposition of silicon nitride to a thickness of about 25 nm. By implantation at an angle of 45 to the surface O with the aid of a fourth mask (not shown), which is analogous to the third mask, and with the aid of the reduced-size first mask M1, a first part S/D1a of a first source/drain region S/D1 (see FIG. 2) is created at peripheral regions of the semiconductor structure St. Remaining portions of the doped thin film SF form a second part S/D1b of the first source/drain region S/D1. The implantation is done at about 25 keV, and as a result a second dimension, relative to a y axis y that extends perpendicular to the x axis x and to the z axis, of the first part S/D1a of the first source/drain region S/D1 is larger than a second dimension, relative to the y axis y, of the second part S/D1b of the first source/drain region S/D1. The dopant concentration of the first part S/D1a of the first source/drain region S/D1 is about 10²¹ cm⁻³. The thin film Sd of silicon nitride serves as a scattering layer in the creation of the first part S/D1a of the first source/drain region S/D1.

By deposition of SiO₂ to a thickness of 150 nm by a TEOS process, a second layer S2 is created.

By masked etching, a first via-hole V1 is created above an inner region of a surface OH of the semiconductor structure St that extends perpendicular to the y axis y. In this process, the second layer S2, the thin film Sd of silicon nitride, and the first layer S1 are severed, and the first source/drain region S/D1 is partly laid bare. As the etchant, CHF₃/O₂/Ar is for instance suitable. After that, a scattering oxide (not shown) about 20 nm thick is deposited.

By implantation at about 35 keV, a doped region G with a second conductivity type, opposite the first conductivity type, is created underneath the second part S/D1b of the first source/drain region S/D1. The doped region G reduces short-channel effects, such as punch-through, and leakage currents resulting from a parasitic bipolar transistor.

Next, by masked etching above a part of the source/drain region S/D2, a second via-hole V2 is created, until the second source/drain region S/D2 is partly laid bare.

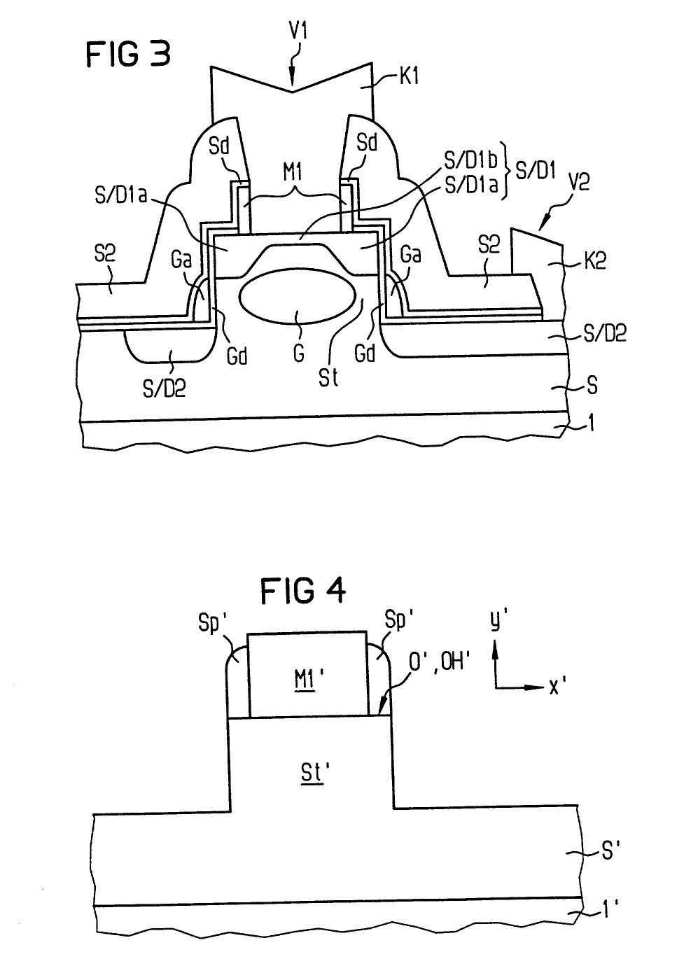

To create a contact K1 for the first source/drain region S/D1 and a contact K2 for the second source/drain region S/D2, selective siliconizing is first done, and then aluminum is deposited and structured (see FIG. 3).

In a second exemplary embodiment, a second substrate 1′ of silicon is p-doped in a layer S′ adjoining a surface O′ of the second substrate 1′. The dopant concentration of the layer S′ is about 1×10¹⁵ cm⁻³. By deposition of SiO₂ in a TEOS process, a first layer about 150 nm thick is created on the surface O′. To create a first mask M1, the first layer is structured by a photolithographic process, analogously to the first exemplary embodiment. The first mask M1 is about 600 nm long relative to an x axis x′ that extends parallel to the surface O′. The first layer S1′ is about 2000 nm long (see FIG. 4) relative to a z axis, which extends parallel to the surface O′ and perpendicular to the x axis x′.

To create an auxiliary spacer Sp′ at flanks of the first mask M1′, silicon nitride is deposited to a thickness of about 50 nm and back-etched. As the etchant, CHF₃O₂/Ar is for instance suitable.

Next, silicon is selectively etched to silicon nitride and SiO₂ to a depth of about 200 nm, thus creating a semiconductor structure St′ underneath the first mask M1′ and the auxiliary spacer Sp′. As the etchant, HBr/NF₃/He,O₂ is for instance suitable (see FIG. 4).

For cleaning etching residues resulting from the etching of silicon, a sacrificial layer (not shown) of SiO₂ about 5 nm thick is grown on by thermal oxidation. The sacrificial layer is subsequently removed by wet etching, for instance using 1% HF etchant.

To create a gate dielectric Gd′, SiO₂ about 4 nm thick is grown on by thermal oxidation (see FIG. 5).

Next, in-situ-doped polysilicon is deposited to a thickness of about 80 nm. Analogously to the first exemplary embodiment, polysilicon is etched with the aid of a third mask (not shown), which covers a second flank and a region on the far side of the semiconductor structure St. On flanks of the semiconductor structure St′, this creates a gate electrode Ga′ in the form of a spacer, and on the second flank of the semiconductor structure St′, it creates a terminal for the gate electrode Ga′ (see FIG. 5). As the etchant, HBr/NF₃/He,O₂ is for instance suitable. With the aid of H₃PO₄, for example, the auxiliary spacer Sp′ is removed. Next, a thin film Sd′ is created, by depositing silicon nitride to a thickness of about 30 nm (see FIG. 5).

By implantation at an angle of about 45 to the surface O′ with the aid of a second mask (not shown), which does not cover a region around first flanks of the semiconductor structure St′, a first part S/D1a′ of a first source/drain region S/D1′ is created at peripheral regions of the surface OH′ of the semiconductor structure St′, and a second source/drain region S/D2′ is created outside the semiconductor structure St′. The implantation is done at an energy of about 25 keV, so that a second dimension of the first part of the first source/drain region S/D1′ is about 100 nm long relative to a y axis y′ that extends perpendicular to the surface C′.

To create a second layer s2′, SiO₂ is deposited to a thickness of about 150 nm in a TEOS process. By masked etching, a first via- hole V1′ is created above an inner region of a surface OH′ of the semiconductor structure St′ that extends perpendicular to y axis y′. In the process, the second layer s2′, the thin film Sd′ of silicon nitride, and the first mask M1′ are severed, and the source/drain region S/D1′ is partly is laid bare.

Next, a doped region G′, with a conductivity type opposite the first conductivity type, is created underneath the inner region of the surface OH′ of the semiconductor structure St′, by implantation with an energy of about 35 keV. The dopant concentration of the doped region G′ is about 10¹⁹ cm⁻³.

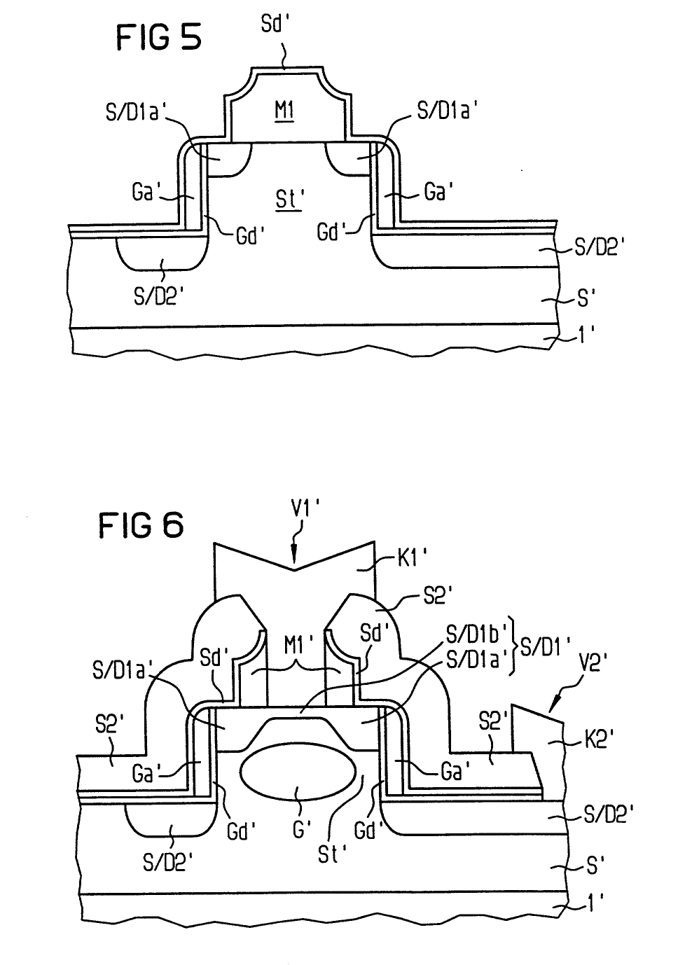

To create a second part S/D1b′, doped with the first conductivity type, of the first source/drain region S/D1′, implantation is then done with an energy of about 20 keV (see FIG. 6). A second dimension of the second part S/D1b′ of the first source/drain region S/D1′ relative to the y axis y′ is about 50 nm, and is thus less than the second dimension of the first part S/D1a′ of the first source/drain region S/D1′ relative to the y axis y′.

Next, outside the semiconductor structure St′, a second via-hole V2′ is etched, until the second source/drain region S/D2′ is partly laid bare. By selective siliconization, the second part S/D1b′ of the first source/drain region S/D1′ is siliconized in the first via-hole V1′, and part of the second source/drain region S/D2′ is siliconized in the second via-hole V2′. To create a contact K1′ of the first source/drain region S/D1′ and a contact K2′ of the second source/drain region S/D2′, aluminum is then deposited and structured (see FIG. 6).

Many variations of the exemplary embodiments that are also within the scope of the invention are conceivable. In particular, the dimensions of the layers, regions, masks and structures described can be adapted to given conditions. The same is true for the proposed dopant concentrations. The form of the surface of the semiconductor structure need not be square but instead can be adapted to given requirements. The flanks of the semiconductor structure need not extend perpendicular to the surface of the semiconductor structure but instead can form an arbitrary angle with the surface of the semiconductor structure. Masks and layers of SiO₂ can be created by thermal oxidation or by a deposition process. The first layer can also contain other materials that, for instance like silicon nitride, are etchable selectively relative to the material of the substrate. The second layer can also contain different insulating materials, such as silicon nitride. Polysilicon can be doped either during or after the deposition. Instead of doped polysilicon, metal silicides and/or metals can also be used, for instance.

The sacrificial layer can be dispensed with, for instance if only slight etching residues occur in the creation of the semiconductor structure.

We claim:

1. A method for producing a vertical MOS transistor, which comprises:
forming a semiconductor structure with a first flank and a surface;
producing a gate dielectric on the first flank of the semiconductor structure;
forming a gate electrode bordering on the gate dielectric;
producing a first part, doped with a first conductivity type, of a first source/drain region inside the semiconductor structure and bordering on at least a part of the first flank, by implantation with a first mask not covering at least a peripheral region of the surface of the semiconductor structure;
forming a second source/drain region, doped with the first conductivity type, and located, with respect to a y-axis extending perpendicular to the surface of the semiconductor structure, lower than the first source/drain region;
wherein the first part of the first source/drain region is created such that a first dimension of the first part of the first source/drain region perpendicular to the first flank is less than a minimum feature size F to be attained by the technology employed.

2. The method according to claim 1, which comprises
producing a second part, doped with the first conductivity type, of the first source/drain region S/D1 inside the semiconductor structure and bordering on the first part of the first source/drain region;
forming the second part of the first source/drain region to border substantially on an inner region of the surface OH of the semiconductor structure adjoining the peripheral region; and
creating the first source/drain region such that a second dimension of the second part of the first source/drain region, which extends parallel to the y-axis is less than a second dimension of the first part of the first source/drain region extending parallel to the y axis.

3. The method according to claim 1, which comprises:
forming a channel region between the first source/drain region and the second source/drain region, the channel region being doped with a second conductivity type opposite the first conductivity type and having a first dopant concentration;
forming a region inside the semiconductor structure, the region being doped with the second conductivity type and having a second dopant concentration higher than the first dopant concentration; and
wherein the region is formed substantially underneath the inner region of the surface of the semiconductor structure.

4. The method according to claim 1, which comprises:
at least partly removing the first mask and laying bare the inner region of the surface of the semiconductor structure; and
subsequently creating at least one of the region and the second part of the first source/drain region by implantation.

5. The method according to claim 1, which comprises:
creating a first layer on a surface of a substrate;
etching the first mask out of the first layer;
etching semiconductor material with the aid of the first mask, for creating the semiconductor structure;
reducing a size of the first mask by isotropic etching, and thereby uncovering the peripheral region of the surface of the semiconductor structure; and
wherein the first part of the first source/drain region is created with the first mask reduced in size.

6. The method according to claim 1, which comprises:
creating a first layer on a surface of a substrate;
etching the first layer for forming the first mask;
creating an auxiliary spacer by deposition and back-etching of material on flanks of the first mask;
etching the semiconductor material and forming the semiconductor structure with the aid of the first mask and the auxiliary spacer; and
subsequently removing the auxiliary spacer prior to creating the first part of the first source/drain region.

7. The method according to claim 1, which comprises forming the second source/drain region substantially laterally to the semiconductor structure.

8. The method according to claim 7, which comprises creating the second source/drain region and the first part of the first source/drain region simultaneously.

9. The method according to claim 7, which comprises creating the second source/drain region by implantation prior to creating the gate electrode.

10. The method according to claim 2, which comprises:
forming the second source/drain region with a second mask covering at least a second flank of the semiconductor structure;
forming a terminal of the gate electrode at the second flank of the semiconductor structure;
forming the gate electrode and the terminal of the gate electrode by depositing material and etched the material with a third mask covering the second flank of the semiconductor structure and extending to a distal side of the semiconductor structure; creating a second layer;
prior to forming the second part of the first source/drain region, forming a first via-hole substantially above the inner region of the surface of the semiconductor structure, by etching the second layer and the first mask until the surface of the semiconductor structure is partly laid bare;
forming a second via-hole by removing a part of the second layer until a part of the second source/drain region is laid bare; and
after forming the second part of the first source/drain region, producing a contact of the first source/drain region in the first via-hole, and producing a contact of the second source/drain region in the second via-hole, by depositing and structuring conductive material.
